(19) United States
(12) Patent Application Publication
(10) Pub. No.: US 2024/0019469 A1
(43) Pub. Date: Jan. 18, 2024

(54) SYNCHRONOUS REVENUE GRADE POWER SENSOR

(71) Applicant: Dave Engineering, LLC, Chesterfield, MO (US)

(72) Inventor: Dave JONES, St. Charles, MO (US)

(21) Appl. No.: 18/338,144

(22) Filed: Jun. 20, 2023

Related U.S. Application Data
(60) Provisional application No. 63/353,696, filed on Jun. 20, 2022.

(51) Int. Cl. G01R 22/06

(52) U.S. Cl. CPC G01R 22/065

(57) ABSTRACT

A sensor device and platform for low-cost electrical power metering, ground fault monitoring, and ground fault current interruption applications is claimed herein. The platform employs flux gate sensors employed in a novel PCB arrangement that affords simple, inexpensive production by using symmetric arrangements and heavy copper inner layers. The combination of elements allows flux gate sensors to be printed directly onto the plane of the PCB, improving the form factor over prior designs. A unique signal processing method employed in tandem permits highly accurate no-contact power measurement with minimal noise and a high tolerance for variation in temperature.

### CROSS-REFERENCE TO RELATED APPLICATIONS

This application claims priority to U.S. Provisional Patent Application No. 63/353,696, filed Jun. 20, 2022, the contents and teachings of which are herein incorporated by reference.

### STATEMENT REGARDING FEDERALLY SPONSORED RESEARCH OR DEVELOPMENT

Not applicable.

### BACKGROUND OF THE INVENTION

Non-contact electrical power sensors have been engineered for a variety of applications. Such sensors rely on a variety of physical phenomena for their respective principles of operation. Among these is the flux gate sensor, which operates by sensing changes in the flux of a local magnetic field. Flux gate sensors are traditionally constructed to comprise three components: a conductive and magnetically permeable core, a ‘drive’ winding of wire wound around that core, and a ‘sense’ wire wound around the same core for the purpose of sensing changes in magnetic flux. As the drive winding generates a dynamic local magnetic field, it moves the permeable core through a full hysteresis cycle. Alterations to the magnetic flux pattern of this hysteresis cycle, such as those caused by an impinging field, are detected by the sense coil.

While very useful, flux gate sensors are traditionally understood to have problems and limitations that have confined their use to a somewhat narrow domain of applications. One such limitation is that the sensor is understood to benefit from careful control of constituent materials; the permeable core, for example, is best made from a ‘soft’ material with a narrow hysteresis loop and stark saturation points. Similarly, driving and sense windings need to be constituted and engineered so as to be sensitive to small changes in magnetic flux without interfering with one another. Thus, the need for relatively rarer or more expensive materials is a limitation. Additionally, the principle of operation is such that each flux gate sensor is necessarily anisotropic and must therefore be oriented properly with respect to any field it means to sense. While this problem is theoretically soluble through the use of multiple flux gate sensors oriented along different axes, such a solution typically renders simple, layer-by-layer printed circuit board (PCB) integration infeasible. As a result, despite the otherwise relative simplicity and high sensitivity of flux gate sensors, their actual implementation typically either requires significant structural compromise and/or added expense, such that they have frequently been superseded by less-promising sensor designs.

For revenue grade metering, field measurements are generally required to have ±2% accuracy. Presently, most revenue grade metering is performed using current transformer (CT) coils. These typically are constructed using silicon steel and copper wire windings. Such CT coils have their own construction constraints in order to meet revenue grade, and often include materials such as rare earth coils and magnetic wire. CT coils are also susceptible to saturation, which is a problem that must be attended to via degaussing. Flux gate sensors, by contrast, saturate and desaturate easily as part of their core design principle. In addition, despite their historical limitations, they are extremely robust against noise and temperature changes. Finally, they are extremely sensitive, theoretically capable of sensing magnetic field strengths measured as small as picoteslas (pT).

There are existing commercial models for metering that use flux gate sensors. For example, a currently available metering device design uses a bus bar with integrated flux gate sensor devices to measure current up to 100 A. However, this bus bar model requires that holes be drilled into the bus bar to accommodate PCB-borne flux gate sensors in at least two orientations. While the device appears capable of metering, it has a bulky, cumbersome form factor unsuitable for many applications. Furthermore, the sizes of the one or more holes drilled into these ‘bus bar’ designs have a direct impact on the signal-to-noise ratio of the flux gate sensor output; this incentivizes one to create ever-smaller holes for ever-higher signal-to-noise ratios. The unreachable ideal of such a design is one with a nonexistent hole.

Therefore, there exists a need for low-cost PCB designs with robust integrated flux gate sensors absent the material demands and infeasible construction constraints of past designs. The present invention aims to provide a solution for this need by using a novel PCB design in tandem with advanced construction and signal processing techniques.

In the following sections of this disclosure, a system, device, and method that overcome the shortcomings of prior art systems, devices and methods is disclosed. Description of specific embodiments is provided merely to illustrate non-limiting examples. Variations known to be acceptable or obvious to those of ordinary skill in the art are considered to be within the scope of the present invention.

### BRIEF SUMMARY OF THE INVENTION

A sensor device and platform, comprising a method of construction, general circuit design, and signal processing and control techniques, is provided for herein. The benefits of this invention include that the device and platform are smaller, less expensive, and capable of high resolution alternating current (AC) and direct current (DC) current and voltage sensing over a wide temperature range. Furthermore, the PCB design cuts down on the required number of layers and keeps the device on the scale of inches, all while using common, relatively inexpensive, and easily-sourced materials.

The sensor device and platform disclosed herein offers non-contact isolation, ensuring separation of the measured current and the measurement system, and obviates the shunt resistor present in many metering designs, which helps to avoid undesired power loss. The use of flux gate operating principles also keeps noise and drift levels lower than is typically seen when measuring magnetic fields with, for example, Hall effect sensors. The PCB platform disclosed features a construction incorporating inner heavy copper layers typically taught against by prior art that nevertheless produce unexpectedly positive results herein. Moreover, the particular disclosed combination of known parts and materials is itself novel and offers advantages over existing prior art in the areas of form factor, ease of construction, noise cancelation, range of operation, and stability against surge current and thermal variation.

This ultimately results in a sensor platform that is constructed without weaving methods, that reduces more common layer counts, that eliminates rare earth metals, and that nevertheless provides highly accurate bi-directional differential measurements. The parallel topology of its construction, at least one embodiment of which features two fluxgate sensors in 180° opposition that sense current in the inner layers of the PCB, enables a small and mechanically and thermally stable system with higher than expected range. The construction cost of the device is reined in by the relatively simple method of its construction and the elimination of expensive and exotic materials such as rare earth metals. With self-healing saturation, isolated sensors that do not suffer shunt loss, high sensitivity, and a bandwidth in at least one embodiment of 23 kHz, the present invention nevertheless boasts a rough ‘order of magnitude’ bill of materials as low as six dollars per phase, and perhaps lower.

Circuitry design and software further enable the device. Synchronization and frequency sweeping techniques provide a platform that can function as a revenue grade power meter, perform as a ground monitor interrupter, a ground fault circuit interrupter, measure line impedance and power factor, and implement real-time temperature compensations for active cancelation and accuracy improvements over a broad operational range. These features render the claimed platform ideal for electric vehicle charging applications, for example.

These and other details of the present disclosure will be discussed in detail in the following detailed description. Other aspects of the invention will be apparent to those skilled in the art in light of the following description of preferred embodiments of the invention.

### BRIEF DESCRIPTION OF THE SEVERAL VIEWS OF THE DRAWINGS

FIGS. 1A, B, and C present diagrammatic views of embodiments of the PCB board with varying numbers and integrations of the flux gate sensors as well as modules required for signal processing.

FIG. 2A presents a side view of the PCB board as assembled, including insulating materials, thick copper plating, vias, wiring, and representative flux gate sensors on either side.

FIG. 2 B presents a similar, more simplified side view of an alternate embodiment with more flux gate sensors for multi-phase measurement.

FIGS. 2 C and D depict simplified top and bottom perspectives of the simplified board depicted in FIG. 2A, denoting relative orientations of the opposing flux gate sensors.

FIG. 3 is a simplified diagram depicting the processing routine for synchronized frequency variable power data delivered from the sensors.

FIG. 4 presents a diagrammatic view of another PCB embodiment featuring specific circuit board features for the purpose of estimating materials cost.

### DETAILED DESCRIPTION OF THE INVENTION

The following description of illustrative embodiments of the invention is by way of illustration and not limitation, the scope of the disclosure being defined by the claims, specification and figures taken together.

The term ‘heavy copper’ is used hereinafter to refer to the use of metal or metal alloy of weight in excess of 4 oz/ft² on a printed circuit board. While copper is typically the metal used in such an application, applicant does not seek to limit the present disclosure to only copper, as other conductive metals and metal alloys can serve the same purpose. Terminology familiar to those in the art that refers to variations in the techniques required for such metal application, or to the use of even higher densities of metal in PCB construction, are herein subsumed under the umbrella term ‘heavy copper’ for the sake of simplicity.

The term ‘via’ is used hereinafter to refer to electrically conductive elements positioned transverse to the plane of the PCB board so as to engender one or more electrically conductive path through one or more layers of PCB.

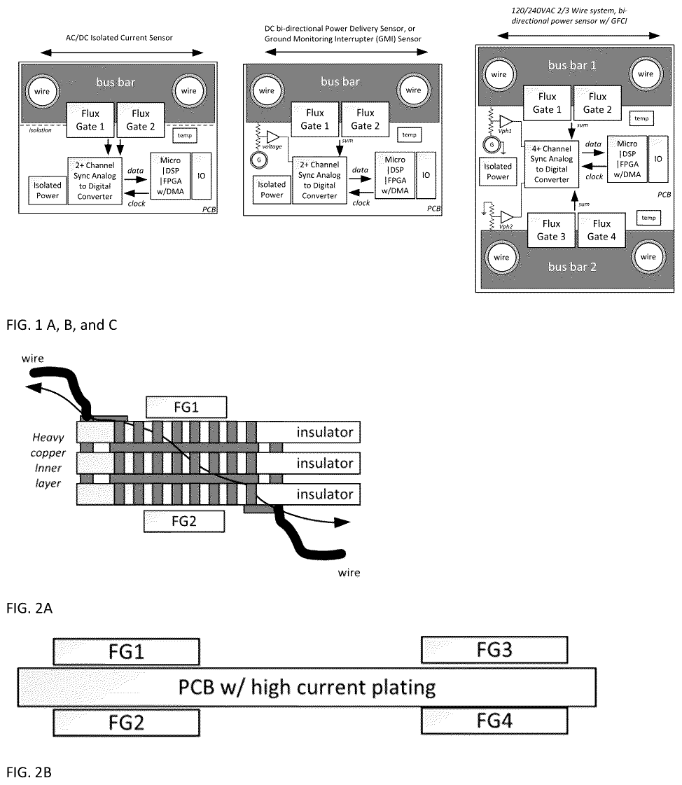

Referring now to the drawings, and in particular to FIG. 1, the illustrative embodiments depicted in parts A, B, and C are schematic depictions of PCB constructions suitable for the labeled applications. The appearance of particular elements such as flux gate sensors, operational amplifiers, et cetera is intended to suggest their presence and functional interdependence, and not their size or position on a PCB. FIG. 1A depicts the isolated nature of the bus bar and flux gate sensor combination that permits it to act as an AC/DC isolated current sensor. Data from both flux gates is sent to the processing modules. Although not seen here, flux gate sensors are oriented 180 degrees opposite one another. The flux gate sensors themselves have internal compensation coils and thus do not require external coils.

FIG. 1 B depicts the additional use of techniques to create an embodiment that functions as a Ground Monitoring Interruptor (GMI) sensor or as a bi-directional DC power delivery sensor. A ground contact is included, as well as an operational amplifier, and the sum of the flux gate sensor outputs is supplied to the signal processing modules. This summation of flux gate sensor outputs has the benefit of suppressing noise.

FIG. 1 C depicts a similar embodiment, but with additional bus bars, flux gate sensors, and an additional operational amplifier distinct from the one connected to the ground. This allows the system to function not only as a 120/240V AC bi-directional power sensor, but also to function with ground fault current interruption (GFCI) ability. A similar signal processing module set is depicted, albeit with expanded channel capability compared to embodiments in FIGS. 1A and B.

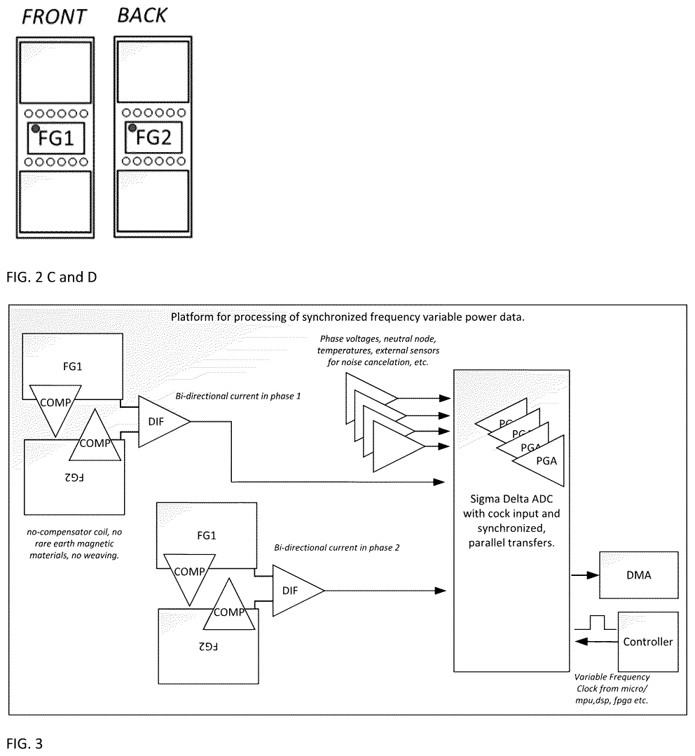

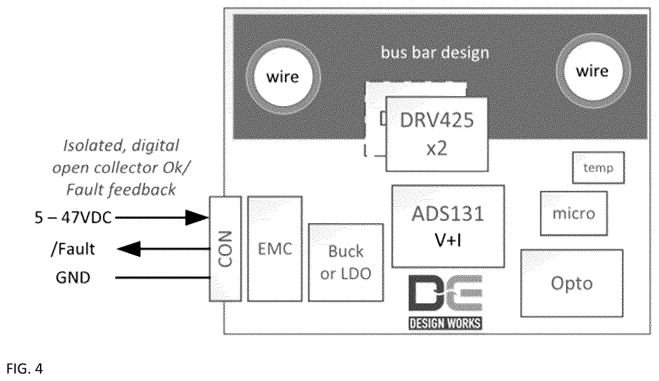

FIG. 2A depicts a side view of an embodiment of the sensor platform, intended to illustrate the use of heavy copper inner layers as well as conductive ‘vias,’ or conductive strips that run transverse to the surface of the PCB stack-up. Note that the two depicted flux gate sensors, ‘FG1’ and ‘FG2’, rest on opposite faces of the sensor platform. FG1 rests on what is referred to hereafter as the “upper face” of the platform, which also bears most of the major circuitry, while FG2 rests on the “lower face” of the platform. ‘Heavy copper’ application is a recently-developed technique that sees the use of relatively massive copper weights in PCB constructions. This and similar techniques are typically recommended against due to the limitations they impose, such as the need for maintaining a relatively high level of symmetry in the board's construction, and the relatively easy manner of carrying thermal energy along the PCB surface for easier dispersal. The device disclosed herein is able to maintain sufficient symmetry to use these layers to full effect, however. The use of heavy copper in the inner layers in this embodiment makes the embodiment robust enough to handle surge currents. Additionally, in combination with the via pattern, the layout of the heavy copper inner layers maintains ideal thermal distribution across the board, as the heavy copper effectively acts as a conductively-transferred-heat sink. In at least one embodiment, the PCB may contain at least 1 ounce of heavy copper in the inner PCB layers per square inch of PCB surface area. In at least one embodiment, the PCB may contain at least 1.5 ounces of heavy copper in the inner PCB layers per square inch of PCB surface area. In at least one embodiment, the PCB may contain at least 2 ounces of heavy copper in the inner PCB layers per square inch of PCB surface area. In at least one embodiment, the PCB may contain at least 2.5 ounces of heavy copper in the inner PCB layers per square inch of PCB surface area. In at least one embodiment, the PCB may contain at least 3 ounces of heavy copper in the inner PCB layers per square inch of PCB surface area. In at least one embodiment, the PCB may contain at least 3.5 ounces of heavy copper in the inner PCB layers per square inch of PCB surface area. In at least one embodiment, the PCB may contain at least 4 ounces of heavy copper in the inner PCB layers per square inch of PCB surface area. In at least one embodiment, the PCB may contain at least 4.5 ounces of heavy copper in the inner PCB layers per square inch of PCB surface area. In at least one embodiment, the PCB may contain at least 5 ounces of heavy copper in the inner PCB layers per square inch of PCB surface area. In at least one embodiment, the complete PCB-based sensor platform measures between approximately 0.5 and 5 inches in length and between approximately 0.5 and 5 inches in width, length and width herein understood as the defining dimensions of the surface areas on which circuitry elements are primarily constructed.

A very significant advantage of the inner layers of heavy copper, paired with vias, is that these layers can carry current in a way analogous to the bus bar used in other flux gate sensor designs. However, whereas the bus bar in such designs is an external device mounted onto a system meant to be monitored, the current carrying component of the instant disclosed embodiment is core to the PCB construct itself. Furthermore, vias linked to these heavy copper inner layers run orthogonally to it, and to the surface of the board, thereby reorienting the electric field generating by electrical current. This reorientation is ideally suited for the orientation of the flux gate sensors on opposite sides of the board. In this way, proper orientation of current and sensors is maintained in a compact form factor without sacrificing surge capacity or relying on alternative sensor principles with more exotic and expensive material constraints. This also permits the disclosed embodiments of sensor platforms to comprise as few as four layers in construction of the PCB.

Further, it should be noted that simplicity of construction is a core aspect of the disclosed invention. The use of heavy copper inner layers significantly simplifies board construction particularly with respect to vias by limiting the number of connectors required. The application of heavy copper and implementation of vias during board construction comprises techniques known to those of ordinary skill in the art, arranged in substantially linear and planar geometric forms. Thus, there is no need for manufacture of woven designs, spiral patterns, or other complex means of generating flux gate sensor-like designs within the PCB itself. Instead, a valuable innovation of the construction of the PCB permits the integration use of commercially-available flux gate sensors, rendering the disclosed embodiments of sensing platforms robust to separate innovations in the flux gate sensor materials themselves.

Additionally, the use of heavy copper inner layers lends greater mechanical strength to the PCB itself, which is undeniably an advantage of the present design over the prior art.

The construction of a sensor platform embodiment as disclosed herein enables a wide range of current, voltage, and temperature conditions for operation. In at least one preferred embodiment, the sensor platform is capable of up to 100 A continuous current measurement. In at least one preferred embodiment, the sensor platform is capable of operating between −40 and 150 degrees Celsius. In a preferred embodiment, the sensor platform can handle 240V AC current or 300 V DC current. Note that as stated, these are non-limiting embodiments provided for illustration; the voltage limits, for example, are nominally a matter of safety guidelines and decided by spacing between PCB elements, which can be increased or decreased as desired.

FIG. 2 B depicts a similar side view, further simplified, with additional flux gate sensors depicted to demonstrate multi-phase sensing capability. Multiple layers within the PCB structure are implied but not shown.

FIGS. 2 C and D depict simplified diagrams of front and back sides of the PCB with opposed flux gate sensors clearly labeled ‘FG1’ and ‘FG2.’ The use of a dot in the upper-left corner of each box labeled ‘FG1’ or ‘FG2’ is used to denote the relative orientation of each flux gate sensor.

The disclosed sensor platform embodiment comprises circuitry and software to interface with the flux gate sensors. The modules used in this circuitry and software comprise temperature compensation modules that improve measurement accuracy over a temperature range, synchronization modules for proper timing of current, voltage, and other inputs, frequency sweep impedance measurement modules, and a programmable gain stage for extending operation.

FIG. 3 depicts a diagrammatic, simplified illustration of the circuitry used to deliver and process the signal from the flux gate sensors. Note the compensated operational amplifiers operatively linked to each flux gate sensor. Two pairs of flux gate sensors are depicted to connote the sensor platform's capacity to sense bidirectional alternating current with distinct phases. Data from these sensors can, in a preferred embodiment, be fed through differential amplifiers, and then into a Sigma Delta analog-to-digital converter (ADC) with clock input and synchronized, parallel transfers. In a preferred embodiment, this data is transmitted concomitantly with data from neutral nodes, temperature sensors, external sensors calibrated to reduce noise, and data related to phase voltages. A direct memory access and controller are also operationally linked to the Sigma Delta ADC at this point.

In at least one embodiment, the sensor platform comprises a module with onboard memory suitable for generating a clocking signal and onboard Sigma Delta ADC. Alternatively, the sensor platform may comprise a module that provides the clocking signal and memory required to interface with a separate Sigma Delta ADC. Candidates for such a module include, but are not limited to, a microcontroller (MCU), microprocessor (MPU), digital signal processor (DSP), field programmable gate array (FPGA) or tensor flow parallel processing unit (TPU). In a preferred embodiment, the ADC features synchronized conversion and may incorporate direct memory transfers (DMAs) and a programmable gain array (PGA) that can maintain accurate measurement of low currents by providing additional gain. The synchronization feature of the ADC is necessary to avoid timing errors otherwise common to such measurements; such errors frequently vary over the range at which ADC conversion frequency occurs.

In at least one embodiment, the frequency of conversion can be varied. This variation can constitute a measurement of the impedance values of circuit components. Such impedance measurements enable or contribute to onboard safety and connectivity verification algorithms, as well as ground fault interruption (GFI) and ground fault monitoring (GMI) applications.

Numerous variations, within the scope of the appended claims, will occur to those skilled in the art.

All patents, patent applications, and literature mentioned herein are hereby incorporated by reference.

1. An electrical power sensor platform, comprising:
a printed circuit board comprising an upper face, a lower face, and at least one heavy copper layer;
one or more flux gate sensors oriented to receive an electromagnetic wave propagated along a receiving axis;
one or more vias in contact with the heavy copper layer and oriented to direct electromagnetic waves originating from electrical current along said receiving axis of said one or more flux gate sensors; and
integrated circuitry and modules to receive and process one or more signals received from said one or more flux gate sensors.

2. The sensor platform of claim 1, wherein the printed circuit board comprises four layers.

3. The sensor platform of claim 1, further comprising at least two flux gate sensors, and each of the at least two flux gate sensors is paired with another one of the at least two flux gate sensors, said pairing arrangement such that each paired flux gate sensor is rotated 180 degrees relative to the other, and placed on the opposite face of the PCB.

4. The sensor platform of claim 3, further wherein each pair of flux gate sensors is operationally linked to a differential operational amplifier.

5. The sensor platform of claim 1, wherein said at least one heavy copper layer is positioned between upper and lower PCB layers not made of heavy copper.

6. The sensor platform of claim 1, wherein said at least one heavy copper layer has weight such that the density of heavy copper in the sensor platform is at least 1 ounce of heavy copper per square inch of surface area of said upper face.

7. The sensor platform of claim 1, wherein said integrated circuitry and modules comprise a synchronized analog-to-digital converter and non-transient computer-readable medium on which data from said one or more flux gate sensors can be stored and recalled.

8. The sensor platform of claim 1, wherein the surface area of a face of the PCB does not exceed 2.5 square inches.

9. A method for processing one or more signals from one or more flux gate sensors, comprising the steps of:
receiving data from other modules;
receiving clocking data generated to ensure that signals generated synchronously are processed synchronously; and
converting all analog signals to digital signals.

10. The method of claim 9, wherein said other modules comprises temperature sensors, clocking modules, and impedance measurement modules.

11. The method of claim 9, wherein the analog to digital signal conversion occurs by way of a Sigma Delta analog-to-digital converter.

12. The method of claim 11, further wherein the analog-to-digital converter is configured to perform impedance measurements by sweeping the frequency of signal conversion.
